(19) United States
(12) Patent Application Publication
(10) Pub. No.: US 2019/0051802 A1
(43) Pub. Date: Feb. 14, 2019

(54) SEMICONDUCTOR COMPONENT AND METHOD FOR PRODUCING A SEMICONDUCTOR COMPONENT

(71) Applicant: OSRAM Opto Semiconductors GmbH, Regensburg (DE)

(72) Inventors: Korbinian PERZLMAIER, Regensburg (DE); Christian LEIRER, Friedberg (DE); Matthias SPERL, Mintraching (DE)

(21) Appl. No.: 16/078,561

(22) PCT Filed: Feb. 21, 2017
(86) PCT No.: PCT/EP2017/053910

§ 371 Date: Aug. 21, 2018

(30) Foreign Application Priority Data
Feb. 22, 2016 (DE) 10 2016 103 059.7

(51) Int. Cl. H01L 33/62; H01L 25/13; H01L 33/00; H01L 33/52; H01L 33/50; H01L 33/48

(52) U.S. Cl. CPC H01L 33/62; H01L 25/13; H01L 33/486; H01L 33/52; H01L 33/50; H01L 33/0095

(57) ABSTRACT

The invention relates to a semiconductor component comprising at least one semiconductor chip (10) having a semiconductor body (1) with an active region (12), a conversion element (6) and a carrier (3), the carrier (3) comprising a first moulded body (33), a first conductor body (31) and a second conductor body (32), the conductor body (31, 32) being connected to the active region (12) in an electrically conducting manner. A side of the conversion element (6) facing away from the active region (12) forms a front side (101) of the semiconductor chip (10) and a side of the carrier (3) facing away from the active region (12) forms a rear side (102) of the semiconductor chip (10), and lateral surfaces (103) of the semiconductor chip connect the front side (101) and the rear side (102) together. The semiconductor component also comprises a second moulded body (5), the semiconductor chip (10) fully penetrating the second moulded body (5) in such a way that the second moulded body (5) forms a frame around the semiconductor chip (10), and the front side (101) and the rear side (102) of the semiconductor chip (10) are free from the second moulded body (5) at least in places, and the second moulded body (5) at least partially covers free surfaces of the conversion element (6) on the lateral surfaces of the semiconductor chip (10).

The document US 2012/0119233 A1 describes a semiconductor component and a method for producing a semiconductor component.

An object to be solved is to specify such a semiconductor component which can be produced in a particularly cost-effective manner. Another object to be solved is to provide a method for producing such a semiconductor component.

These objects are achieved in particular by a semiconductor component according to one of claims 1 to 14 or by a method according to one of claims 15 to 19. Hereby, the disclosure content of the claims is expressly incorporated by reference into the present description.

A semiconductor component, in particular an optoelectronic semiconductor component, is specified. The optoelectronic semiconductor component can be set up to emit and/or detect electromagnetic radiation, in particular light, during operation.

In accordance with at least one embodiment of the semiconductor component, the semiconductor component comprises at least one semiconductor chip. The semiconductor chip may be an electronic or an optoelectronic semiconductor chip. If the semiconductor chip is an optoelectronic semiconductor chip, then the semiconductor chip is set up to emit and/or detect electromagnetic radiation, in particular light, during operation. The semiconductor chip may then be a light-emitting diode chip, for example. In this case, the semiconductor component is a light emitting diode.

The semiconductor chip comprises a semiconductor body with an active region. In the active region of the semiconductor body, during operation of the semiconductor chip, the function of the semiconductor chip, for example the generation of light, is effected. For example, the semiconductor body is grown at least partially epitaxially and is based on a III-V compound semiconductor material.

The semiconductor chip comprises a conversion element and a carrier which comprises at least one first conductor body, at least one second conductor body and at least one first molded body. The carrier is, in particular, one or the mechanically supporting component of the semiconductor chip, which gives the semiconductor chip at least part of its mechanical stability.

During operation, the semiconductor chip can be energized through the conductor bodies, wherein the first conductor body and the second conductor body lie at a different electrical potential. The conductor bodies are formed, for example, as a solid body containing at least one metal or consist of at least one metal. The conductor bodies can be provided, for example, as solid bodies for the production of the carrier, or the conductor bodies are produced in the production of the carrier, for example by electroless or galvanic deposition. The conductor bodies are characterized by a high electrical conductivity and a high thermal conductivity. If the carrier comprises two or more first conductor bodies, these are at the same potential during operation of the semiconductor chip. Also, any two or more present second conductor bodies may be at the same potential during operation of the semiconductor chip, which is different from the potential on which the first conductor bodies lie.

The conductor body can therefore be formed in one piece or in several parts. If a conductor body is designed in several parts, all parts of the multi-part conductor body are at the same electrical potential.

The carrier further comprises a first molded body. The first molded body is formed with an electrically insulating material. For example, the first molded body may be formed with a plastic material. The first molded body may partially or completely enclose the conductor bodies of the carrier in lateral directions. The lateral directions are those directions which are parallel to a main extension plane of the semiconductor chip. It is possible that the conductor bodies completely penetrate the first mold body, so that the conductor bodies each have at least two opposing exposed surfaces that are not covered by the first mold body. The conductor bodies can terminate flush with the first molded body on a side of the carrier facing the semiconductor body and a side of the carrier facing away from the semiconductor body.

The first molded body can be molded onto the conductor bodies. In particular, direct interfaces between the first molded body and the conductor bodies may be present. For example, the material of the first molded body for molding on the conductor body may be flowable and may solidify after molding. The first molded body electrically isolates the first and second conductor bodies from one another, so that electrical connection of the semiconductor body is possible via the conductor bodies. The first molded body is for this purpose at least between the first and the second conductor body. Side surfaces of the carrier, which connect the side facing the semiconductor body of the carrier and the side facing away from the semiconductor body of the carrier, for example, may be formed completely with the first molded body, so that the conductor body only on the side facing away from the semiconductor body side of the carrier, that is, are accessible at the rear side of the semiconductor chip for further contacting. Alternatively, it is possible that the side surfaces are formed at least in places by the conductor body. In this case, the conductor bodies are therefore exposed on the side surfaces of the semiconductor chip and the first molded body is present in the region between the conductor bodies.

The first molded body may be formed in one piece. The first molded body may be formed with a matrix material comprising, for example, a thermoplastic and/or a thermoset and/or an epoxy material and/or a silicone material. In the matrix material fillers may be introduced, which influence mechanical, thermal and/or optical properties of the first molded body.

The semiconductor chip comprises a conversion element. The conversion element in this case comprises at least one luminescence conversion material which is set up to convert an electromagnetic radiation generated during operation in the semiconductor chip into radiation of another, in particular a longer wavelength. The conversion element may comprise a matrix material in addition to the at least one luminescence conversion material.

The conversion element can be arranged on the side of the semiconductor body facing away from the carrier, in particular a direct interface between the semiconductor body and the conversion element can be present. In this case, the conversion element is arranged on the semiconductor body such that electromagnetic radiation generated during operation in the active region strikes the conversion element.

The semiconductor chip can comprise, in addition to the semiconductor body, the carrier and the conversion element, further elements such as, for example, contact layers, solder layers, passivation layers and/or adhesion-promoting layers, which can be arranged, for example, on the rear side of the carrier facing away from the semiconductor body.

A side of the carrier facing away from the active area at least partially forms a rear side of the semiconductor chip. A side of the conversion element facing away from the active region at least partially forms a front side of the semiconductor chip. The side surfaces of the semiconductor chip are the surfaces connecting the front side and the rear side of the semiconductor chip with each other.

The semiconductor component comprises a second molded body. The second molded body is formed with an electrically insulating material. For example, the second molded body may be formed with a plastic material. The second molded body can completely enclose the semiconductor chip in the lateral directions. In this case, it is possible for the semiconductor chip to completely penetrate the second molded body in a vertical direction that is perpendicular to the lateral directions. The second molded body can be molded onto the semiconductor chip. In particular, direct interfaces between the second molded body and the semiconductor chip may be present. In particular, then at least one direct interface between the conversion element and the second molded body is present.

For example, the material of the second molded body can be flowable for molding on the semiconductor chip and solidify after molding. Side surfaces of the semiconductor component which connect a front side and a rear side of the semiconductor component with one another may for example be formed completely by the second molded body. In this way it is possible that the semiconductor chip is not covered by the second molded body only on its front side and on its rear side.

The second molded body may be formed in one piece. The second molded body may be formed with a matrix material comprising, for example, a thermoplastic and/or a thermoset and/or an epoxy material and/or a silicone material. In particular, the molded body may comprise silicone, spin-on glass and/or metal. In the matrix material fillers may be introduced, which influence mechanical, thermal, electrical and/or optical properties of the second molded body. The fillers may for example contain or consist of TiO₂. The second molded body may be formed with a material different from the first molded body. It is possible that the first and the second molded body both have different matrix materials and different fillers. However, it is also possible that the two molded bodies, for example, have the same matrix material, but differ from one another with regard to fillers in the matrix material. It is likewise possible that the two molded bodies have different matrix materials and do not differ from one another with regard to the introduced fillers.

According to at least one embodiment of the semiconductor component, the second body completely surrounds the semiconductor chip in lateral directions. That is, the semiconductor chip is enclosed in a frame-like manner by the second molded body, and the side surface of the semiconductor component is completely formed by the second molded body.

According to at least one embodiment of the semiconductor component, the semiconductor chip completely penetrates the second molded body in the vertical direction. That is, the front side and the rear side of the semiconductor chip are at least in places, in particular completely free of the material of the second molded body.

In accordance with at least one embodiment of the semiconductor component, the carrier of the semiconductor chip is connected cohesively to the semiconductor body. The carrier can be detached from the semiconductor body of the semiconductor chip in particular only by destroying at least one of the components of the semiconductor chip. It is possible that both the conductor body of the carrier and the first molded body are connected cohesively to the semiconductor body. For this purpose, a connecting region between the carrier and the semiconductor body can be arranged, which mediates a mechanical connection between the two components of the semiconductor chip.

In accordance with at least one embodiment of the semiconductor component, the active region is electrically conductively connected to the first conductor body and the second conductor body. That is, the active region of the semiconductor chip is electrically connected via the two conductor bodies. In operation, the electrical current necessary for the operation of the semiconductor chip flows via the first and the second conductor body and, via this, supplies the active region.

In accordance with at least one embodiment of the semiconductor component, the second molded body directly adjoins the semiconductor chip. That is, the side surfaces of the semiconductor chip are at least partially covered by the second molded body.

In accordance with at least one embodiment of the semiconductor component, the second molded body directly adjoins the carrier and/or the semiconductor body and/or further elements of the semiconductor chip. Further elements may include, for example, passivation layers, adhesion-promoting layers and/or mirror layers. In other words, the second molded body directly adjoins the semiconductor chip and, for example, forms an intimate connection with the semiconductor chip on the side surfaces of the semiconductor chip, so that the second molded body is permanently mechanically connected to the semiconductor chip. A release of the second molded body from the semiconductor chip is then possible only by destroying one of the components of the semiconductor component. The second molded body forms in this way a housing for the semiconductor chip, in which this is embedded in the lateral directions.

In accordance with at least one embodiment of the semiconductor component, the second molded body at least partially covers exposed areas of the conversion element on the side surfaces of the semiconductor chip. The second molded body may be in direct mechanical contact with these exposed surfaces.

There is further provided a method for producing a plurality of semiconductor components. In particular, a semiconductor component described herein can be produced by the method. That is, all features disclosed for the semiconductor component are also disclosed for the method and vice versa.

In accordance with at least one embodiment of the method, a multiplicity of semiconductor chips are provided, wherein each of the semiconductor chips comprises a semiconductor body with an active region, a conversion element and a carrier with a first conductor body, a second conductor body and a first molded body. The semiconductor chips may in particular be semiconductor chips, as described in more detail in connection with the semiconductor component.

In accordance with at least one embodiment of the method, the semiconductor chips with the side on which the conversion element is located are fastened on an auxiliary carrier. The semiconductor chips can be attached to the auxiliary carrier in particular by means of a thermally or by UV-releasable adhesive. The thermally dissolvable adhesive may comprise, for example, a bonding material in which particles of a material are introduced, which expand under heat and thus allow detachment.

By way of example, the auxiliary carrier may comprise on its side remote from the semiconductor chips a base body which is formed with a rigid, self-supporting material, for example a metal. On its side facing the semiconductor chips, a foil, for example a so-called thermo-release foil (for example REVALPHA tape from Nitto) or a UV release foil can be arranged on the auxiliary carrier via a bonding layer. The semiconductor chips are laterally spaced from each other mounted on the auxiliary carrier.

In accordance with at least one embodiment of the method, the semiconductor chips are formed with a second molded body in such a way that the second molded body completely surrounds the semiconductor chips in lateral directions and the second molded body at least adjoins the side surfaces of the semiconductor chips, in particular directly. In addition, the respective conversion element can directly adjoin the respective carrier and/or semiconductor body. The second molded body is in particular such as has been described in connection with the semiconductor component.

The second molded body can be applied in such a way that it covers the semiconductor chips at their side facing away from the auxiliary carrier, for example completely covered, so that the second molded body has a thickness perpendicular to the main extension plane of the auxiliary carrier that is greater than the thickness of the semiconductor chips. In this case, the second molded body is subsequently thinned such that the semiconductor chips are exposed on the side of the second molded body facing away from the auxiliary carrier. Alternatively, however, it is also possible for the second molded body to be applied in such a way that the sides of the semiconductor chips remote from the auxiliary carrier remain free of the material of the second molded body.

In accordance with at least one embodiment of the method, the auxiliary carrier is removed and the arrangement of semiconductor chips and second molded body is singulated into a multiplicity of semiconductor components, wherein each semiconductor component comprises at least one semiconductor chip.

In accordance with at least one embodiment of the method, the method comprises the following steps:

Providing a multiplicity of semiconductor chips, each of the semiconductor chips comprising a semiconductor body having an active region, a conversion element and a carrier having a first conductor body, a second conductor body and a first molded body,

fixing the semiconductor chips on an auxiliary carrier with the side on which the conversion element is located,

forming the plurality of semiconductor chips with a second molded body, such that the second molded body completely surrounds the multiplicity of semiconductor chips in lateral directions and the second molded body directly adjoins each semiconductor chip,

removal of the auxiliary carrier,

separating into a plurality of semiconductor components, wherein each semiconductor component comprises at least one semiconductor chip.

The steps can be carried out in particular in the order given.

A semiconductor component described herein and a method described herein prove to be surprisingly advantageous in many ways. It is thus possible to choose different materials for the first molded body and the second molded body which are adapted to the requirements of the molded bodies. Due to the fact that the second molded body laterally surrounds the semiconductor chip and thus the first molded body, it is possible to specify a semiconductor component in which no or negligible electromagnetic radiation, for example generated in the active zone, strikes the first molded body during operation. The first molded body can therefore be formed with materials that are sensitive to, for example, the light or UV radiation generated by the semiconductor chip during operation, but are advantageous for example because of good thermal conductivity and/or low cost.

Further, it is not necessary that the first molded body is formed in a certain color or reflectivity. The optical impression of the semiconductor component can be determined by appropriate choice of the material with which the second molded body is formed. It is for example possible that the second molded body is black, colored or reflective white. Since no electromagnetic radiation generated in the semiconductor chip can strike the first molded body, it can be formed with radiation-sensitive materials such as, for example, an epoxy resin or an epoxy-silicone hybrid material. In contrast, the second moldd body can be formed, for example, with a silicone material as matrix material.

If the second molded body completely covers the outer side surfaces of the semiconductor chip and thus also of the conversion element, it can be achieved that electromagnetic radiation is not coupled out of the semiconductor component via the side surfaces of the conversion element or of the semiconductor body or only to a significantly reduced extent. For example, radiation emitted by the side surfaces of the conversion element and / or the semiconductor body is completely or partially reflected or absorbed.

By means of the arrangement of the second molded body on the side surfaces of the semiconductor chip, the optical parameters of the semiconductor component are improved. If, for example, the second molded body is designed to be reflective for the electromagnetic radiation generated in the active zone and converted by the conversion element, a particularly efficient semiconductor component can thereby be formed. By means of the arrangement of the second molded body on the side surfaces of the semiconductor chip, a cross-talk between laterally juxtaposed semiconductor chips is significantly reduced, in particular prevented.

Due to the fact that the semiconductor chip completely penetrates the second molded body in a vertical direction, it is not necessary in the case of the semiconductor component described here to introduce further conductor bodies into the second molded body, which completely penetrate the latter. This allows a particularly cost-effective production of the semiconductor component. That is, it can be dispensed with in particular expensive metallic or semiconductive via elements.

Due to the fact that the cross-sectional area of the semiconductor component is increased by the second molded body parallel to the main extension plane of the semiconductor chip with respect to the cross-sectional area of the semiconductor chip, semiconductor chips with very small edge lengths of, for example, <0.5 mm can be used, of which two or more in a semiconductor component can be present. Because of the second molded body and the producing method described here, such small semiconductor chips are easy to handle and, for example, can be realized as an SMD component.

Since the carrier is formed in the semiconductor chips used only with conductor bodies and the first molded body and the second molded body can also be formed with a low-cost plastic material, can be dispensed semiconductor chips with expensive semiconductor carriers or expensive housing materials of the semiconductor chips.

The following embodiments relate to semiconductor components described herein and to methods for fabricating semiconductor components described herein.

In accordance with at least one embodiment, the second molded body locally adjoins the first molded body in places. In this case, the first molded body is formed, for example, such that it completely surrounds the conductor body of the semiconductor chip in lateral directions and a side surface of the semiconductor chip is formed in places by the first molded body. In this case, it is possible that the adhesion between the first molded body and the second molded body can be made particularly resistant to mechanical stress.

This can be achieved, for example, by selecting materials for the materials of the first and second molded bodies which stick together particularly well. This is possible, for example, in that the first molded body and the second molded body contain the same or similar matrix materials. Furthermore, on its surface facing the second molded body, the first molded body may have structurings, such as roughenings, projections, undercuts and/or indentations, which increase adhesion to the second molded body in that the second molded body engages in these structurings of the first molded body. Alternatively or additionally, surfaces of the first molded body that directly adjoin the second molded body may have chemical modifications of the surface. For example, this surface of the first molded body, which is in direct mechanical contact with the second molded body, may be treated before the application of the second molded body in a plasma or coated with a primer.

This can be achieved, for example, by separating the semiconductor chips during their production by a separation process which generates a roughened outer surface of the first molded body as a singulation track. For example, the semiconductor chips may be separated by sawing, whereby a roughened surface of the first molded body, which has, for example sawing, can arise. The second molded body then engages in this separation tracks and is connected in this way particularly intimately with the first molded body.

In addition, it is possible that the first molded body comprises particulate fillers which are exposed or present on an outer surface of the molded body and thus project into the second molded body and in this way an anchoring between the two moldings is produced.

Furthermore, it is possible that, for example, particulate fillers in the first molded body are removed by etching on the outer surface of the first molded body and the resulting indentations are filled with material of the second molded body and anchoring of the second molded body takes place in the first molded body in this manner.

In accordance with at least one embodiment, the second molded body covers over more than 50%, in particular completely, exposed areas of the conversion element on the side surfaces of the semiconductor chip. The exposed surfaces of the conversion element may have a different length in the vertical direction and may be covered in different sized areas. That is, a portion of the exposed areas may be not at all, partially or completely covered, with a total of at least 50% of the exposed areas being covered.

In accordance with at least one embodiment, the second molded body directly adjoins the semiconductor chip, in particular directly adjoins the carrier and to the conversion element. Thus, there is direct mechanical contact between the second molded body and the semiconductor chip. This advantageously increases the mechanical stability of the semiconductor component. In addition, the second molded body has a protective function for the semiconductor chip. For example, the second molded body protects the semiconductor chip from moisture and/or mechanical damage.

In accordance with at least one embodiment, the second molded body is designed to be reflective at least in places. For example, the second molded body may be reflective at least at the interface at which the second molded body adjoins the semiconductor body of the semiconductor chip and/or the conversion element. For example, in its reflective regions for the impinging electromagnetic radiation produced, for example, in the semiconductor chip during operation, the second molded body has a reflectivity of at least 60%, at least 75%, at least 80%, or in particular at least 90%, for the impinging electromagnetic radiation, for example in the semiconductor chip generated in operation.

For this purpose, it is possible, for example, that the second molded body is filled with particles of a scattering or reflecting filler, for example of a titanium oxide or a zirconium oxide.

In accordance with at least one embodiment, the first molded body is designed to absorb light at least in places. Since it can be advantageously ensured in the present semiconductor component that only slight or no electromagnetic radiation generated in the semiconductor chip impinges on the first molded body, it can be formed with a material that is sensitive to radiation, but for example a particularly high mechanical strength and/or a has particularly high thermal resistance. For this purpose, the material of the second molded body can be filled, for example, with fillers which give the second molded body a colored or black impression that in particular at least 50%, in particular at least 75%, of a radiation impinging on the first molded body is absorbed or reflected. Thus, a maximum of 50%, in particular a maximum of 25%, of a radiation impinging on the first molded body is transmitted.

In accordance with at least one embodiment, the semiconductor body projects beyond the conductor bodies in lateral directions or ends flush with them. That is to say that the conductor bodies, which may extend from the semiconductor body to the side of the second molded body facing away from the semiconductor body, are arranged completely below the semiconductor body in a plan view of the front side of the semiconductor chip and do not protrude laterally beyond the semiconductor body. In this way, and in particular for the case that the conductor bodies are completely enclosed by the material of the first molded body, a sometimes costly anchoring of the conductor bodies in the second molded body may be dispensed and the material for the second molded body has not to be selected with respect to a particularly good adhesion to the conductor body. Since also additional metallic or semiconducting through-contacting elements by the second molded body are not necessary in the present case, this proves to be particularly advantageous.

In accordance with at least one embodiment, the conversion element laterally projects beyond the semiconductor body or terminates flush therewith. By virtue of this arrangement, no or only a reduced fraction of the electromagnetic radiation generated in the semiconductor body can emerge laterally from the semiconductor component past the conversion element without passing through the conversion element.

According to at least one embodiment, an electrically insulating layer covers the carrier at its side facing away from the semiconductor body and the second molded body at its side facing away from the semiconductor body in places. The electrically insulating layer may comprise at least a first opening and at least one second opening. The openings in the electrically insulating layer penetrate them completely. In the region of the opening, no material of the electrically insulating layer is present.

The electrically insulating layer is formed, for example, with a dielectric. The electrically insulating layer may contain, for example, one of the following materials or may consist of one of the following materials: oxide, nitride, silicone, epoxy resin, polymer. In particular, it is also possible for the electrically insulating layer to be formed with the same material as the first molded body and/or the second molded body or with the same material as the matrix material of at least one of the molded bodies.

The electrically insulating layer has a thickness which is smaller than the thickness of the second molded body. Further, it is possible that the thickness is smaller than the thickness of the first molded body. For example, the thickness of the electrically insulating layer is at most 10% of the thickness of the second molded body or at most 10% of the thickness of the first molded body. In this way, the electrically insulating layer hardly represents an obstacle to heat, which is brought to it via the conductor body.

Through the first opening of the electrically insulating layer, a first connection point can be connected to the first conductor body, and a second connection point can be connected to the second conductor body through the second opening of the electrically insulating layer. The connection points serve for contacting the semiconductor chip from the outside and are arranged, for example, on a common surface, for example on the rear side of the semiconductor chip and on the rear side of the second molded body, that is to say the rear side of the semiconductor component. The semiconductor chip and thus the semiconductor component can be surface mountable in this case.

The pads are formed with an electrically conductive material and may include one or more metals. In particular, the connection points may have an outer surface facing away from the semiconductor body, which is characterized by good connectivity, for example good solderability.

Alternatively, the two connection points are applied to the rear side of the semiconductor component and there is an electrically insulating layer between the two connection points. In this case, the connection points form two areas separated by the insulating layer. The connection points may in this case extend to a side surface of the semiconductor component.

The first conductor body preferably has a first distance from the second conductor body and the first connection point has a second spacing from the second connection point, wherein the first distance is smaller than the second distance. The conductor bodies are therefore closer together than the connection points.

In particular, it is possible that the second distance, i.e. the distance between the connection points, is at least 1.45 times the first distance. The distance between the conductor bodies may then be 100 μm or smaller, for example 60 μm and smaller or 40 μm and smaller.

The semiconductor component described here and the method described here are based inter alia on the recognition that a cross section of the conductor bodies in a plane parallel to the main extension plane of the semiconductor chip is decisive for the thermal behavior of the semiconductor chip. The larger the cross section of the conductor body, the better heat can be dissipated via the conductor body from the active area. In particular, a large distance of the conductor body leads to an inhomogeneous heat dissipation of the semiconductor body and thus to loss of efficiency. Furthermore, inhomogeneous heat dissipation can lead to an inhomogeneous light pattern as well as to locally increased temperatures in the semiconductor chip, which ultimately results in faster aging of the semiconductor chip.

On the other hand, the distance between the conductor bodies may not be too small, if the semiconductor chip is connected from the outside directly through the conductor bodies, i.e. they expose at the rear side of the semiconductor chip, otherwise a minimum distance, which is required for example for connecting the semiconductor chip by means of soldering , is not respected. A semiconductor component described here now comes in a surprising manner against the two mentioned reluctant requirements - a small distance of the conductor body to improve the thermal properties and a large distance between the connection points to facilitate a connection process, in particular a soldering.

In a semiconductor component or producing method described here, an electrically insulating layer is applied to the rear side of the carrier and the second molded body facing away from the semiconductor body, which isolates the conductor body on its side facing away from the semiconductor body and forms a new electrically insulating rear side of the semiconductor component. The electrically insulating layer is open or absent at locations where the connection points are formed and the connection points are connected via this opening with the electrical conductor bodies.

In this way, it is possible to form the conductor body with a sufficiently small distance, without having to consider restrictions in the later connection process of the semiconductor component. The electrically insulating layer may extend over the entire rear side of the second molded body facing away from the semiconductor body, so that the molded body there is completely covered by the electrically insulating layer.

In accordance with at least one embodiment, the electrically insulating layer partially borders directly on the conductor body, the connection points and the first molded body and the second molded body. The electrically insulating layer can thus serve as a mechanically connecting component between said components of the semiconductor component and further increase a mechanical stability of the semiconductor component.

According to at least one embodiment of the semiconductor component, it may comprise a plurality of semiconductor chips spaced apart in the second molded body. The semiconductor chips may be similar semiconductor chips which, for example, emit light of the same color during operation. Alternatively, it is possible that they are different semiconductor chips, which can emit, for example, light of different colors.

The semiconductor chips are each embedded in the described manner in the second molded body. An electrical interconnection of the semiconductor chips, for example in a series or parallel connection, can take place via corresponding structuring of the electrically insulating layer and the connection points. Furthermore, it is possible for an interconnection of the semiconductor chips to take place only by mounting the semiconductor component on a correspondingly structured connection carrier, for example a printed circuit board.

In accordance with at least one embodiment of the method, a multiplicity of semiconductor chips are arranged on the auxiliary carrier such that the conversion element of each semiconductor chip faces the auxiliary carrier and the carrier of each semiconductor chip is remote from the auxiliary carrier. In this way, it is possible to thin the second molded body after wrapping the semiconductor chips on the auxiliary carrier, without having to accept too high a risk of damaging the semiconductor body or the conversion element.

According to at least one embodiment, the conversion element comprises at least one luminescence conversion material which is set up to convert an electromagnetic radiation generated in operation in the semiconductor chips into radiation of another, in particular a longer wavelength. For example, the semiconductor component produced in this way can emit mixed light, for example white mixed light, during operation. The conversion element may comprise a matrix material in addition to the at least one luminescence conversion material. The conversion element is applied, for example, by spraying, knife coating or spin coating. Alternatively, the conversion element may be formed as a self-supporting element. The conversion element can then be produced in a separate process and subsequently applied to the semiconductor body.

In the present method, it is possible, in particular, for the semiconductor chips to be pre-sorted with respect to the wavelength of the light emitted by them during operation before they are mounted on the auxiliary carrier. This process is also called binning. In this way, the color locus of the resulting mixed light, which is generated by conversion of the conversion element and primary radiation from the semiconductor chips, can be adjusted particularly accurately because with a uniform layer thickness of the conversion element all semiconductor chips of the composite of semiconductor chips and second molded body emit the same or substantially the same primary radiation.

In the following, the semiconductor component described here as well as the method described here are explained in greater detail on the basis of exemplary embodiments and the associated figures.

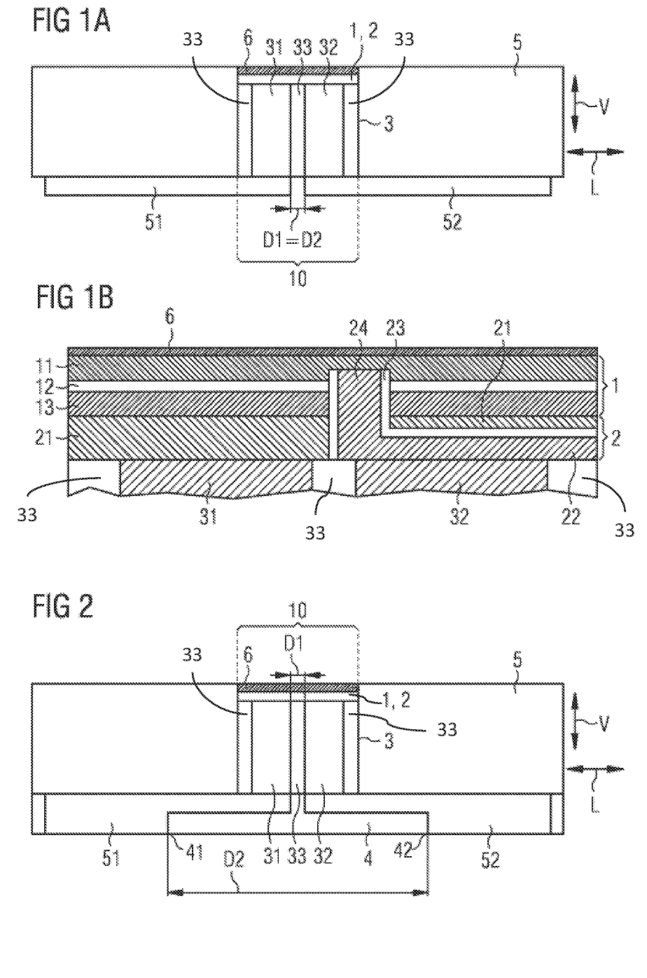

FIGS. 1A, 1B, 2 and 3A and 3B show exemplary embodiments of semiconductor components described here in schematic views.

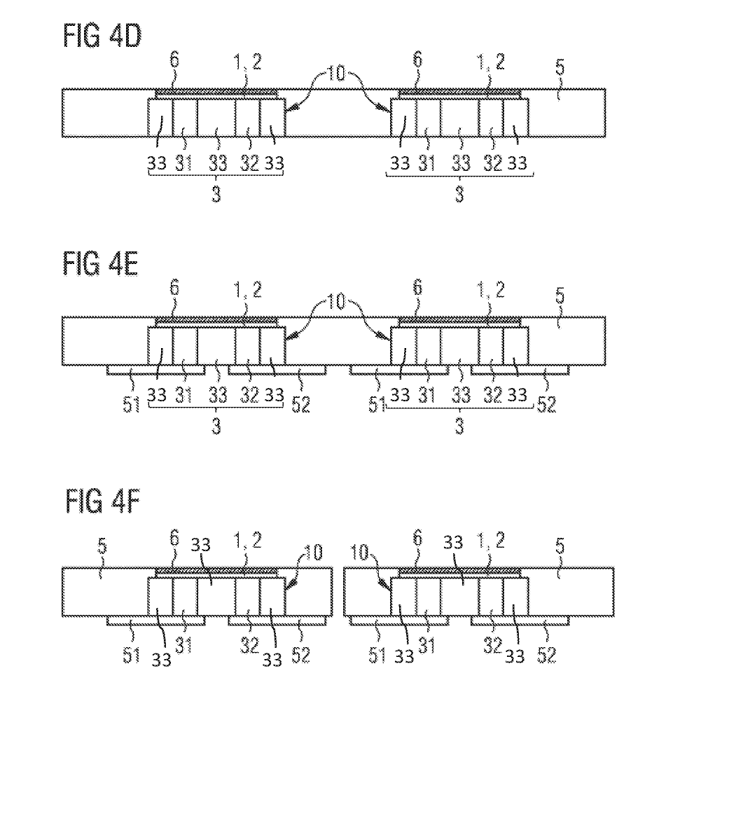

FIGS. 4A, 4B, 4C, 4D, 4E and 4F show, with reference to schematic sectional representations, method steps of an exemplary embodiment of a method described here.

FIG. 1A shows, on the basis of a schematic sectional illustration, a first exemplary embodiment of a semiconductor component described here. The semiconductor component comprises a semiconductor chip 10. The semiconductor chip 10 comprises a semiconductor body 1, a connecting region 2, a carrier 3 and a conversion element 6. The semiconductor body 1, the connecting region 2 and the conversion element 6 are shown in more detail in the detail enlargement of FIG. 1B. The semiconductor body 1 is fastened and connected mechanically and electrically to the carrier 3 via the connecting region 2. The conversion element 6 is arranged on the side facing away from the carrier 3 side of the semiconductor body 1. The side of the conversion element 6 facing away from the semiconductor body 1 forms the front side 101 of the semiconductor chip 10 and the side of the carrier facing away from the semiconductor body 1 forms the rear side 102 of the semiconductor chip 10. Lateral surfaces of the carrier 3, the connecting region 2 and the semiconductor body 1 form at least a part of the side surfaces 103 of the semiconductor chip 10, which connect the front 101 and rear side 102.

The carrier 3 comprises a first conductor body 31, a second conductor body 32 and a first molded body 33.

The semiconductor body 1 includes, for example, a first conductive region 11, which may be formed, for example, n-type, an active region 12 and a second conductive region 13, which may be formed, for example, p-type. During operation of the semiconductor component, a function of the semiconductor chip takes place in the active region 12. For example, the semiconductor chip 10 can be a radiation-emitting semiconductor chip in which light is generated in operation in the active region 12, for example blue light. The semiconductor chip 10 is then, for example, a light-emitting diode chip.

The semiconductor body 1 is mechanically fixed and electrically conductively connected to the carrier 3 via the connecting region 2. That is, the semiconductor body 1 can be detached only by destroying at least one of the components of the semiconductor chip 10 from the carrier 3. The connecting region 2 comprises, for example, a first contact layer 21, via which the second conductive region 13 of the semiconductor body 1 is contacted, and a second contact layer 22, via which the first conductive region 11 of the semiconductor body 1 can be contacted. For example, the first conductive region 11 is contacted by the second contact layer 22 by a via 24. The via 24 and the second contact layer 22 may be electrically separated from the first contact layer 21 by an insulating layer 23. The plated-through hole 24 extends from the side of the semiconductor body facing away from the carrier 3 through the second conductive region 13 and the active region 12 into the first conductive region 11.

The first contact layer 21 may, for example, be reflective for the electromagnetic radiation generated during operation of the active region 12. In a preferred embodiment, at least a majority of the electromagnetic radiation generated in the active region impinges on the conversion element 6.

In the exemplary embodiment of FIGS. 1A and 1B, the first contact layer 21 and the second contact layer 22 extend parallel to one another in places and overlap in the vertical direction V, which runs perpendicular to the lateral directions L, which run parallel to a main extension plane of the semiconductor chip or of the semiconductor component.

The connecting region 2 can comprise further layers that are set up for current conduction and/or for other functions in the semiconductor chip, such as a reflection of electromagnetic radiation.

Moreover, it is possible that the semiconductor body 1 and the connecting region 2 are formed differently than shown. For example, the semiconductor body 1 could be contacted without plated-through holes or contact layers of the connecting region 2 do not run one above the other in the vertical direction.

In the present exemplary embodiment, the carrier 3 comprises a first conductor body 31 and a second conductor body 32. The first conductor body 31 is electrically conductively connected to the first contact layer 21 and the second conductor body 32 is electrically conductively connected to the second contact layer 22. The conductor bodies 31, 32 are formed, for example, with a metal and produced galvanically, wherein a layer of the connecting region 2 can serve as a seed layer for the electrodeposition of the conductor bodies 31, 32. Furthermore, it is possible for the conductor bodies 31, 32 to be formed as solid bodies, which are connected to the semiconductor body 1 via solder layers, which may likewise be parts of the connecting region 2.

In the present case, the conductor bodies 31, 32 are completely enclosed by the first molded body 33 in the lateral directions L and terminate flush with the first molded body 33 on the front side facing the semiconductor body 1 and the rear side of the carrier 3 facing away from the semiconductor body 1. The conductor body 31, 32 are arranged at a distance D1 to each other.

A similar embodiment of such a semiconductor chip 10 is described, for example, in German patent applications DE 102015114587.1 and DE 102015115900.7, the disclosure content of which is hereby expressly incorporated by reference.

The semiconductor chip 10 is completely surrounded in the lateral directions L by a second molded body 5 which directly adjoins the carrier 3 as well as the semiconductor body 1, the connecting region 2 and the conversion element 6. In the present case, the semiconductor chip 10 completely penetrates the second molded body 5 in the vertical direction V.

At the rear side of the conductor body 31, 32, of the first molded body 33 and of the second molded body 5, facing away from the semiconductor body 1, first and second connection points 51, 52 are formed, which form the connection points for mounting and for an electrical connection of the semiconductor component.

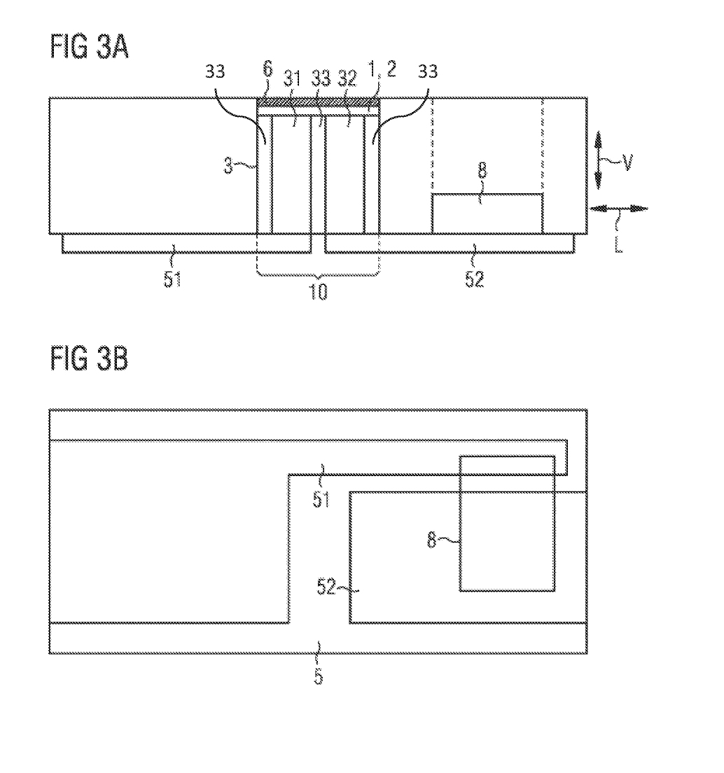

In the exemplary embodiment according to FIG. 2, the semiconductor component has an electrically insulating layer 4 on a rear side of the second molded body 5. The electrically insulating layer 4 covers the second molded body and the first molded body 33 at least in places and is in direct contact with the moldings 5, 33. In this embodiment, it has openings 41, 42, in which material of the connection points 51, 52 is arranged, which is, for example, a metal. The connection points 51, 52 are located in the openings 41, 42 in direct contact with the conductor bodies 31, 32. The connection points 51, 52 are arranged at a distance D2 from each other, which is greater than the distance D1 between the conductor bodies 31, 32. In this way, a solderability of the semiconductor component is facilitated. But it is also possible that the electrically insulating layer 4 is present exclusively between the connection points 51, 52 and not on the side surfaces of the component.

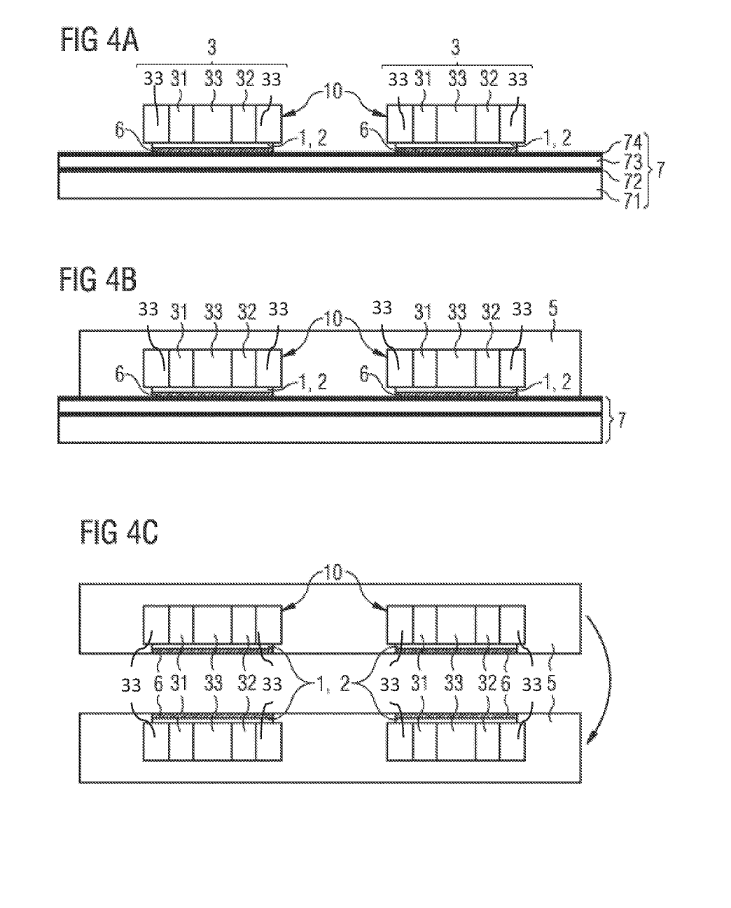

In conjunction with the schematic representations of FIGS. 3A and 3B, a further exemplary embodiment of a semiconductor component described here is described in which a planar ESD protection diode is introduced as ESD protection element 8 into the second molded body 5 and which is at least partially embedded there. The ESD protection element 8 may have a thickness in the vertical direction that, for example, at most corresponds to the thickness of the second molded body 5 and penetrates it completely in this case. An interconnection of the ESD protection element 8, for example antiparallel to the active region 12 of the semiconductor chip 10, can then take place by appropriate structuring of the connection points 51, 52, as shown schematically in the plan view of FIG. 3B.

In conjunction with FIGS. 4A to 4F, an exemplary embodiment of a method for producing a semiconductor component described above is explained with reference to schematic sectional views. In the method, a multiplicity of semiconductor chips 10 are provided, which may, for example, be light-emitting diode chips, for example as described above, which are pre-sorted, for example, with respect to electromagnetic radiation emitted during operation.

The semiconductor chips 10 are arranged facing the auxiliary carrier 7 with the side on which the conversion element 6 is located. The auxiliary carrier 7 comprises, for example, a main body 71 which is formed with a rigid material, for example a metal. Furthermore, the auxiliary carrier 7 comprises a connecting layer 72, with which a foil 73 is attached to the main body 71. The foil 73 is, for example, a thermally dissolvable foil which comprises a thermally dissolvable adhesive 74 on its side remote from the main body 71, with which the semiconductor chips 10 are fastened with their front side 101 to the auxiliary carrier in a thermally releasable manner.

In a next step (see FIG. 4B), the second molded body 5 is applied, for example, by means of mounts in such a way that it is arranged between and above the semiconductor chip 10. In particular, the second molded body covers the side surfaces 103 and the rear sides 102 of the semiconductor chips.

In a next method step (see FIG. 4C), the auxiliary carrier 7 is detached from the second molded body 5 as well as from the semiconductor chips 10.

Thereafter (see FIG. 4D), a process step in which the second molded body 5 is thinned, for example, by grinding, so that on its rear side, the first conductor body 31 and the second conductor body 32 are exposed. This process step can be omitted if the second molded body 5 does not over-mold the semiconductor chips 10 as seen from the auxiliary carrier 7, but the front side of the semiconductor chips 10 remote from the auxiliary carrier 7 remains free from the second molded body 5. For example, the molded body 5 may be applied by transfer molding.

In a next method step (see FIG. 4E), the application of the connection points 51, 52 can take place, via which the semiconductor chips 10 can also be interconnected with each other in an electrically conductive manner.

In the following there is still a singulation to individual semiconductor components, see FIG. 4F, which each comprise at least one semiconductor chip 10.

The invention is not limited by the description based on the embodiments of these. Rather, the invention encompasses any novel feature as well as any combination of features, which includes in particular any combination of features in the patent claims, even if this feature or combination itself is not explicitly stated in the patent claims or exemplary embodiments.

This patent application claims the priority of German Patent Application 102016103059.7, the disclosure of which is hereby incorporated by reference.

### LIST OF REFERENCE NUMBERS

1 semiconductor body
11 first conductive region
12 active region
13 second conductive region
2 connecting region
21 first contact layer
22 second contact layer
23 insulating layer
24 via
3 carrier
31 first conductor body
32 second conductor body
33 first molded body
4 electrically insulating layer
41 first opening
42 second opening
5 second molded body
51 first connection point
52 second connection point
6 conversion element
7 auxiliary carrier
71 main body
72 connecting layer
73 foil
74 adhesive
8 ESD protection element
10 semiconductor chip
101 front side
102 rear side
103 side surface

1. Semiconductor component
with at least one semiconductor chip, comprising a semiconductor body having an active region, a conversion element and a carrier, and the carrier comprises a first molded body, a first conductor body and a second conductor body, and the conductor bodies are electrically connected to the active region, and in which a side of the conversion element facing away from the active region forms a front side of the semiconductor chip and a side of the carrier remote from the active region has a rear side of the semiconductor chip, and side surfaces of the semiconductor chip connect front and rear, and
with a second molded body, wherein
the semiconductor chip completely penetrates through the second molded body, such that the second molded body forms a frame around the semiconductor chip and that the front side and the rear side of the semiconductor chip are at least in places free from the second molded body, and the second molded body covers exposed surfaces of the conversion element on the side surfaces of the semiconductor chip at least partially.

2. Semiconductor component according to claim 1, wherein the second molded body covers exposed surfaces of the conversion element on the side surfaces of the semiconductor chip to more than 50%, in particular completely.

3. Semiconductor component according to claim 1, in which the second molded body directly adjoins the semiconductor chip, in particular directly adjoins the carrier and the conversion element.

4. Semiconductor component according to claim 1, in which the second molded body completely surrounds the semiconductor chip in lateral directions (L).

5. Semiconductor component according to claim 1, in which the second molded body locally directly adjoins the first molded body.

6. Semiconductor component according to claim 1, in which the second molded body is designed to be reflective at least in places.

7. Semiconductor component according claim 1, in which the first molded body is formed at least in places light-absorbing.

8. Semiconductor component according to claim 1, wherein the semiconductor chip in lateral directions projects beyond the conductor bodies or finishes flush with them.

9. Semiconductor component according to claim 1, in which the conversion element projects beyond the semiconductor chip in lateral directions or finishes flush therewith.

10. Semiconductor component according to claim 1 with
an electrically insulating layer,
a first connection point which is electrically conductive, and a second connection point which is electrically conductive, wherein
the electrically insulating layer covers in places the carrier at its rear side facing away from the semiconductor body and the second molded body,
the first connection point is electrically conductively connected to the first conductor body,
the second connection point is electrically conductively connected to the second conductor body,
the first conductor body has a first distance from the second conductor body,
the first connection point has a second distance to the the second connection point on the side of the electrically insulating layer facing away from the semiconductor chip, and
the first distance is smaller than the second distance.

11. Semiconductor component according to claim 10, in which
the electrically insulating layer comprises a first opening and a second opening,
the first connection point through the first opening is electrically conductively connected to the first conductor body, and
the second connection point through the second opening is electrically conductively connected to the second conductor body.

12. Semiconductor component according to claim 10, wherein the electrically insulating layer locally directly borders the conductor body, the connection points, the first molded body and/or the second molded body.

13. Semiconductor component according to claim 1, wherein the semiconductor component comprises a plurality of semiconductor chips, which are arranged laterally spaced from each other in the second mold body.

14. Semiconductor component according to claim 13, in which a plurality, in particular all semiconductor chips are electrically connected in series or in parallel.

15. Semiconductor component according to claim 1, in which the second molded body is formed with a material different from the first molded body.

16. A method of manufacturing a semiconductor component comprising the steps of:
providing a plurality of semiconductor chips, wherein each of the semiconductor chips comprises a semiconductor body with an active region, as well as a conversion element and a carrier with a first conductor body, a second conductor body and a first molded body,
fixing the semiconductor chips on an auxiliary carrier with the side on which the conversion element is located,
forming the plurality of semiconductor chips with a second molded body, such that the second molded body surrounds the plurality of semiconductor chips in lateral directions and the second molded body covers side surfaces of the conversion element at least in places,
removing the auxiliary carrier,
separating into a plurality of semiconductor components, wherein each semiconductor component comprises at least one semiconductor chip.

17. Method according to claim 16, wherein the multiplicity of semiconductor chips are arranged on the auxiliary carrier such that the conversion element of each semiconductor chip faces the auxiliary carrier and the carrier of each semiconductor chip faces away from the auxiliary carrier.

18. Method according to claim 15, wherein the second molded body has a thickness which is greater than the thickness of the semiconductor chips, after forming the semiconductor chips perpendicular to the main extension plane of the auxiliary carrier.

19. Method according to claim 18, wherein the second molded body is thinned such that the semiconductor chips are exposed on the side of the second molded body which faces away from the auxiliary carrier.

20. A method according to claim 16, wherein a semiconductor component according to any one of claims 1 to 15 is produced.

21. Semiconductor component according to claim 1, in which the second molded body is formed with a material different from the first molded body.
